(19) United States
(12) Patent Application Publication
(10) Pub. No.: US 2004/0217344 A1
(43) Pub. Date: Nov. 4, 2004

(54) Apparatus and method of employing self-assembled molecules to function as an electron injection layer of OLED

(76) Inventors: Ta-Ya Chu, Taipei (TW); Gwo-Sen Lin, Taichung (TW)

Correspondence Address: BIRCH STEWART KOLASCH & BIRCH, PO BOX 747, FALLS CHURCH, VA, 22040-0747, US

(21) Appl. No.: 10/426,621

(22) Filed: May 1, 2003

(51) Int. Cl. H01L 35/24

(52) U.S. Cl. 257/40

(57) ABSTRACT

An apparatus and method of employing self-assembled molecules to function as an electron injection layer of organic light emitting diodes (OLEDs) uses self-assembled molecules to function as an electron injection layer. A dipolar self-assembled molecules film is formed on a cathode metal layer to serve the electron injection layer. The self-assembled molecules have dipolar properties. The doner and the cathode metal layer form a key bond. The resulting dipolar direction formed in the self-assembled molecules can increase electron injection efficiency, thereby increase light emitting efficiency of OLED elements and reduce the threshold voltage of the OLED elements.

### FIELD OF THE INVENTION

The present invention relates to an apparatus and method that employs self-assembled molecules to function as an electron injection layer of organic light emitting diodes (OLEDs) and particularly to an approach that use dipolar properties of self-assembled molecules to enhance electron injection capability and transport efficiency.

### BACKGROUND OF THE INVENTION

OLED has many advantages, such as self illumination, small thickness, fast response time, wide viewing angle, excellent resolution, great brightness, adaptable to flexible panels and wide range of use temperature. It is being considered the most promising technique for the new generation of flat display device after Thin Film Transistor Liquid Crystal Display (TFT-LCD). The principle of OLED uses material characteristics to couple electrons and holes on a emitting layer to generate energy to raise light emitting molecules from a base state to an agitated state. When the electrons are returned from the agitated state to the base state, they release energy in the form of wave. Thus OLED elements may be made to generate light of different wavelengths.

The anode is Indium Zinc Oxide (ITO) conductive glass film formed by sputter plating or vaporization plating on a glass or transparent plastic substrate. The cathode includes metals such as Mg, Al, Li and the like. Between the two electrodes, there is a light emitting zone consisting of many organic films, including a Hole Injection Layer (HIL), a Hole Transport Layer (HTL), an organic Light Emitting Layer and an Electron Transport Layer (ETL). In practical mass production, depending on different requirements, some other layers may be included.

Although the OLED has many advantages, in order to increase light emitting efficiency and reduce the threshold voltage, there is a need to increase the injection of electrons and holes. Hence the material for the cathode layer usually is selected from metal of a low function (such as Mg or Ca) to facilitate injection of electrons. But the metal of low function often is more active and easy to oxidize with moisture and result in damage of the cathode. To remedy this problem, one approach is to use cathode made of composite metal (such as Mg and Ag, Al and Li, ITO, IZO (Indium Zinc Oxide)). Another approach is to place a thin layer of LiF between the cathode and the organic layers. The LiF can effectively reduce the energy barrier of injecting electrons from the cathode to the organic layers.

Conventional manufacturing processes of OLEDs include plating organic light emitting material on the anode conductive layer by vaporization, and finally covering the cathode metal. The energy level of holes from the anode to the organic light emitting layer is more uniform. The energy level difference between the cathode metal and the organic light emitting layers is greater. Hence it is more difficult to overcome the energy barrier required for injecting electrons. The currently known techniques utilize composite materials composed of metal of alkaline family or alkaline earth family and highly stable Al or Ag, ITO or IZO to enhance electron injection capability. However, the generally used LiF for electron injection layer has industrial problems. As the film thickness of LiF must be controlled within 2 nm, the problems in fabrication stability and recurrence are more difficult to overcome.

### SUMMARY OF THE INVENTION

Therefore the primary object of the invention is to resolve the aforesaid disadvantages. The invention employs the dipolar properties of self-assembled molecules and uses the self-assembled molecules as the electron injection layer (EIL) to achieve a fabrication process of a high stability and through material having recurrence to increase electron injection power of the electron injection layer, thereby to increase light emitting efficiency and reduce the threshold voltage.

The invention mainly uses OLEDs that employ self-assembled molecules as the electron injection layer (EIL). First, a cathode metal layer is formed on a substrate; next, a dipolar self-assembled molecule film is formed on the cathode metal layer by a dipping or vaporizing to serve as an electron injection layer (EIL); then an Electron Transport Layer (ETL), an Light Emitting Layer, and a Hole Transport Layer (HTL) are plated by vaporizing in this order; finally a conductive film is plated by sputtering to serve as the anode. Through the dipolar properties of the self-assembled molecules, and bonding of the doner and the cathode metal, the dipolar direction formed in the self-assembled molecules can help to increase electron injection efficiency thereby increase light emitting efficiency of OLED elements and reduce the threshold voltage of the OLED elements.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of the structure of the invention.

FIG. 2 is a schematic view of the dipolar direction of the self-assembled molecules of the invention.

FIG. 3 is a block diagram of the fabrication processes of the invention.

### DESCRIPTION OF THE PREFERRED EMBODIMENT

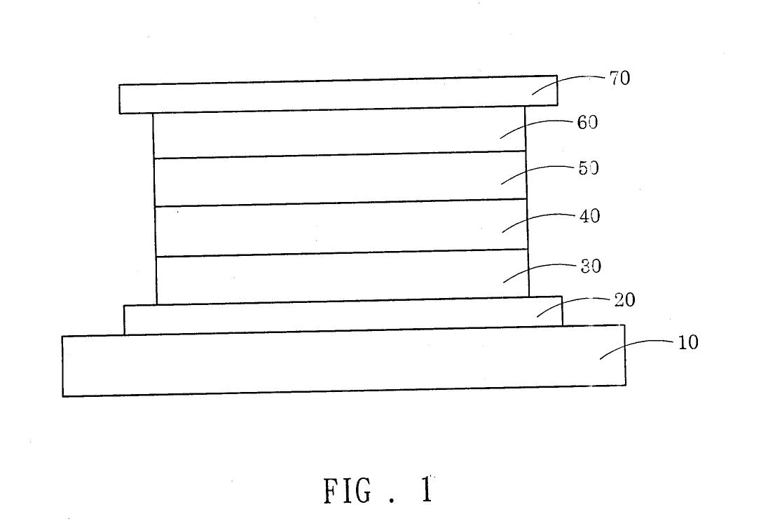

Refer to FIG. 1 for the structure of the invention. The invention includes an OLED substrate 10 upon which a cathode metal layer 20 is formed. The cathode metal layer 20 is made from a composite material consisting of metal of alkaline family or alkaline earth family and Al or Ag, or ITO or IZO. Next, a dipolar self-assembled molecule film 30 is formed on the surface of the cathode metal layer 20 by a dipping or vaporizing. The present self-assembled molecules are aminomethyl phosphonic acid (AMPA). The film thus formed serves as the electron injection layer of OLED elements. Then an Electron Transport Layer (ETL) 40, an Emitting Layer 50, and a Hole Transport Layer (HTL) 60 are plated on the electron injection layer in this order by vaporizing. Finally a conductive film is plated by sputtering to serve as the anode layer 70.

In the general molecules, the acidic root are easy to become acceptor. The alkaline root is doner. The acidic root is easy to form bonding with metal surface, thus hinders electron injection in the dipolar direction. However, in certain conditions the acidic root may become the doner and the alkaline root on another side becomes the acceptor. For instance, AMPA has such a property. Hence using the dipolar properties of the self-assembled molecules AMPA, the doner of the acidic root and the cathode metal may form bonding. The dipolar direction formed by the self-assembled molecules AMPA can increase electron injection efficiency.

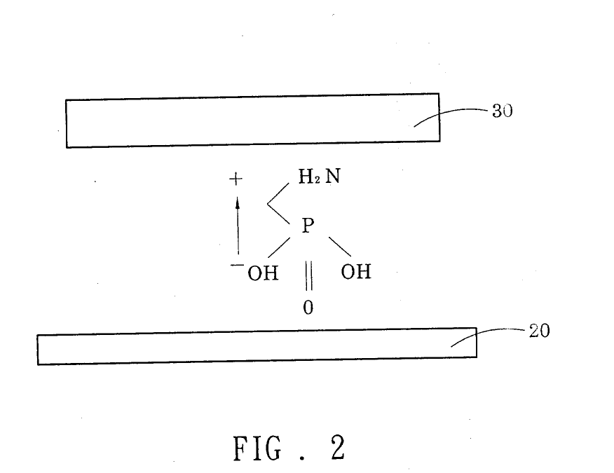

Refer to FIG. 2 for the dipolar direction of the self-assembled molecules of the invention. The dipolar self-assembled molecule film 30 serves as the electron injection layer. The phosphate of the self-assembled molecules forms a bonding with the cathode metal layer 20, therefore the doner of the acidic root forms a key bonding with the cathode metal layer 20, while the acceptor of the alkaline root forms a bonding with the Electron Transport Layer (ETL) 40 to form a dipole in a specific direction.

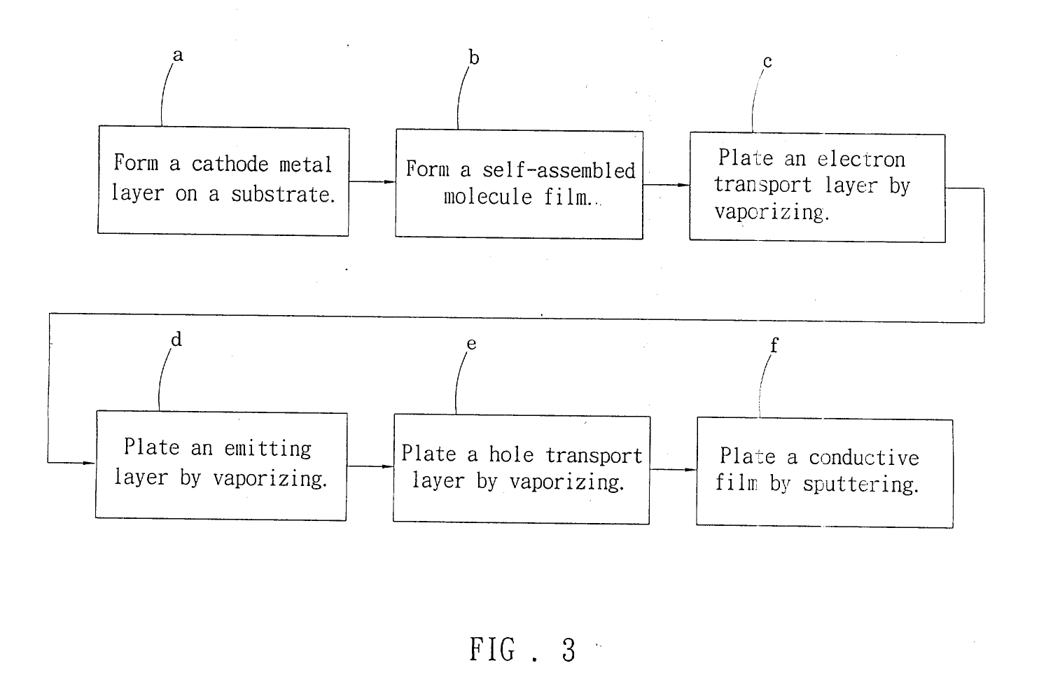

Refer to FIG. 3 for the fabrication processes of the invention. The processes include the following steps:

a. Cleaning a substrate 10 and mapping patterns on the substrate to form a cathode metal layer 20 of an OLED element. The cathode metal layer 20 is made from a composite material consisting of metal of alkaline family or alkaline earth family and Al or Ag, or ITO or IZO.

b. Forming a dipolar self-assembled molecule film 30 by dipping or vaporizing to serve as the electron injection layer (EIL) of the OLED element. The electron injection layer is adhered to the surface of the cathode metal layer 20. The acidic root of the self-assembled molecules is the doner. The dipolar direction of the self-assembled molecules is bonded by the acidic root and the cathode metal layer 20.

c. Plating an Electron Transport Layer (ETL) 40 of the OLED element on the electron injection layer by vaporizing.

d. Plating an Emitting Layer 50 of the OLED element on the Electron Transport Layer (ETL) 40 by vaporizing.

e. Plating a Hole Transport Layer (HTL) 60 of the OLED element on the Emitting Layer 50 by vaporizing.

f. Sputtering a conductive film on the Hole Transport Layer (HTL) 60 to serve as the anode layer 70 of the OLED element.

The “dipole” in the interpretation of physics means two equal electric charges with opposite notations spaced from each other at a definite distance. The product of the electric charges and the relative distance is the dipolar moment which is a physical measurement having a size and direction. The chemical key has dipolar moment. Hence the dipolar moment of the molecule which consists of multiple atoms can be seen as the vector sum of the dipolar moment of every bonding. In electrons, the potential energy coincides with the direction of the dipolar moment. Hence electrons may be easily transported from the negative dipolar location to the positive dipolar location. In contrast, to transport electrons from the positive dipolar location to the negative dipolar location has to overcome an energy barrier. Hence for OLED elements, to inject electrons of the cathode layer to the organic emitting layer 50, the doner (i.e. where the negative dipole is located) of the self-assembled molecules must forms key bond with the cathode metal. Then the dipolar direction formed by the self-assembled molecules is helpful to transport the electrons from the metal cathode layer to the organic emitting layer 50.

In order to accelerate electron injection from the cathode layer to the organic emitting layer 50, through the dipolar properties of self-assembled molecules AMPA (referring to FIG. 2), the acidic root of the self-assembled molecules AMPA may serve as doner to form a key bond with the cathode layer to reduce the energy barrier between the original cathode layer and the organic emitting layer 50. Hence the threshold voltage of the OLED element may be reduced, and electron injection power may increase. As a result, bonding efficiency of electrons and holes on the emitting layer 50 may increase to increase light emitting efficiency.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. An apparatus for employing self-assembled molecules to function as an electron injection layer of organic light emitting diodes (OLEDs), comprising:
a substrate;
a cathode metal layer located on the substrate;
a dipolar self-assembled molecule film located on the cathode metal layer having an acidic root serving a doner to form key bonding with the cathode metal layer and functioning as the electron injection layer;
an electron transport layer located on the electron injection layer;
an emitting layer located on the electron transport layer;
a hole transport layer located on the emitting layer; and
an anode layer located on the hole transport layer;
wherein the self-assembled molecules form a dipolar direction to facilitate increasing of electron injection efficiency and light emitting efficiency of the OLEDs and reducing the threshold voltage of the OLEDs.

2. The apparatus of claim 1, wherein the cathode metal layer is made from materials selected from the group consisting of metal of alkaline family or metal of alkaline earth family and Al or Ag, indium zinc oxide, and indium zinc oxide.

3. The apparatus of claim 1, wherein the self-assembled molecules of the electron injection layer has an acidic root to serve the doner, the dipolar direction of the self-assembled molecules is key bonded by the acidic root and the cathode metal layer.

4. The apparatus of claim 1, wherein the self-assembled molecules are deposited on the surface of the cathode metal layer by dipping.

5. The apparatus of claim 1, wherein the self-assembled molecules are deposited on the surface of the cathode metal layer by vaporizing.

6. A method for employing self-assembled molecules to function as an electron injection layer of organic light emitting diodes (OLEDs), comprising steps of:
a. cleaning a substrate and mapping patterns on the substrate to form a cathode metal layer;
b. forming a dipolar self-assembled molecule film by dipping or vaporizing to serve as the electron injection layer, the electron injection layer being adhered to the surface of the cathode metal layer;
c. plating an electron transport layer on the electron injection layer by vaporizing;
d. plating an emitting layer on the electron transport layer by vaporizing;
e. plating a hole transport layer on the emitting layer by vaporizing; and
f. sputtering a conductive film on the hole transport layer to serve as an anode layer.
